(19) United States
(12) Patent Application Publication
(10) Pub. No.: US 2021/0257024 A1
(43) Pub. Date: Aug. 19, 2021

(54) STORAGE CONTROL DEVICE, STORAGE DEVICE, AND STORAGE CONTROL METHOD

(71) Applicant: SONY SEMICONDUCTOR SOLUTIONS CORPORATION, KANAGAWA (JP)

(72) Inventors: HIDEAKI OKUBO, KANAGAWA (JP); KENICHI NAKANISHI, KANAGAWA (JP)

(21) Appl. No.: 17/250,202

(22) PCT Filed: Mar. 5, 2019
(86) PCT No.: PCT/JP2019/008514

§ 371 Date: Dec. 14, 2020

(30) Foreign Application Priority Data
Jun. 22, 2018 (JP) 2018-119302

(51) Int. Cl. G11C 13/00; G11C 29/42

(52) U.S. Cl. CPC G11C 13/004; G11C 13/0026; G11C 13/0028; G11C 29/42

(57) ABSTRACT

To eliminate drift that is generated in a memory cell and continue use of the memory cell. A storage control device controls a memory cell array in which each bit is in any one of first or second states. The storage control device includes a detection unit and a control unit. The detection unit detects a transition bit that should be in the first state but is in the second state in the memory cell array. The control unit performs control to supply, to the transition bit, a drift refresh voltage higher than a read voltage required for reading from the memory cell array.

### TECHNICAL FIELD

The present technology relates to a storage control device. Specifically, the present invention relates to a storage control device for controlling operation of a memory, a storage device, and a processing method of the devices.

### BACKGROUND ART

In a resistive random access memory (ReRAM) having a cross point structure, each memory cell includes a variable resistance unit and a selector. In such a configuration, if the selector is not snapped (i.e., not turned on) for a long time, drift may occur. The drift has an effect of increasing the voltage required for the selector to snap. In a state where the variable resistance unit of the memory cell is in a low resistance state and drift is occurring, the selector does not snap even when a read voltage is applied, and no current flows through the cell of the cross point memory. As a result, the resistance state of the variable resistance unit is erroneously determined. In order to recover the state of a memory cell in which such a data error is detected, a technology for rewriting data to the memory cell in which data error is detected has been proposed (see Patent Document 1, for example).

### CITATION LIST

### Patent Document

Patent Document 1: Japanese Patent Application Laid-Open No. 2015-038794

### SUMMARY OF THE INVENTION

### Problems to be Solved by the Invention

In the above-mentioned conventional technology, when a memory cell that is in a low resistance state at the time of writing enters a high resistance state due to deterioration of the resistance state, the memory cell is brought back to the low resistance state to recover the state of the memory cell. However, in the above-mentioned conventional technology, a voltage for causing transition to a low resistance state is applied to the memory cell which is in a low resistance state but determined to be in a high resistance state due to the effect of the drift. Thus, the memory cell is forced into a lower low resistance state. As a result, there is a possibility that the memory cell enters a state (overset state) that does not transition to a high resistance state even when a pulse for causing transition of the resistance state is applied, and the memory cell cannot record data normally.

The present technology has been created in view of such a situation, and aims to eliminate drift generated in a memory cell and continue use of the memory cell.

### Solutions to Problem

The present technology has been made to solve the above-mentioned problem, and the first aspect thereof is a storage control device, a storage device, and a control method of the devices, the storage control device including a detection unit that detects, in a memory cell array in which each bit is in any one of first and second states, a transition bit that should be in the first state but is in the second state, and a control unit that performs control to supply, to the transition bit, a drift refresh voltage higher than a read voltage required for reading from the memory cell array. This configuration has an effect of eliminating drift and refreshing to a normal state.

Additionally, in the first aspect, the detection unit may detect the transition bit by comparing values before and after error correction. This configuration has an effect of detecting a memory cell in which the drift is occurring by using the result of the error correction.

Additionally, in the first aspect, the control unit may perform control to secure a new area not including the transition bit in the memory cell array and store the error-corrected value. This configuration has an effect that the area to which the drift refresh voltage is supplied can be reused afterwards.

Additionally, in the first aspect, the control unit may perform control to store the error-corrected value in an area where the drift refresh voltage has been supplied to the transition bit. This configuration has an effect that the area to which the drift refresh voltage is supplied can be continuously used.

Additionally, in the first aspect, the control unit may perform control to supply, to the transition bit, a reset voltage higher than the read voltage and aimed for transition from the first state to the second state as the drift refresh voltage. This configuration has an effect of causing transition to the second state together with the drift refresh.

Additionally, in the first aspect, the control unit may perform control to supply the drift refresh voltage also to a bit in the first state other than the transition bit. This configuration has an effect of drift-refreshing the entire target area.

Additionally, in the first aspect, the control unit may perform control to supply, to a predetermined area of the memory cell array, a reset voltage higher than the read voltage and aimed for transition from the first state to the second state as the drift refresh voltage, the detection unit may detect, as the transition bit, a bit that transitions to the second state by receiving supply of the reset voltage, and the control unit may perform control to supply, to the transition bit, a set voltage higher than the read voltage and aimed for transition from the second state to the first state. This configuration has an effect of causing transition once to the second state together with the drift refresh, and then bringing back the first state for continuous use.

Additionally, in the first aspect, assuming that the memory cell array is a resistive random access memory (ReRAM), the first state is a low resistance state and the second state is a high resistance state. Additionally, the memory cell array is assumed to be a non-volatile memory.

### Effects of the Invention

According to the present technology, it is possible to achieve an excellent effect that drift generated in a memory cell can be eliminated and use of the memory cell can be continued. Note that the effect described herein is not necessarily limited, and the effect may be any of those described in the present disclosure.

### BRIEF DESCRIPTION OF DRAWINGS

FIG. 1 is a diagram showing a configuration example of an information processing system of an embodiment of the present technology.

FIG. 2 is a diagram showing a configuration example of a memory controller 200 of the embodiment of the present technology.

FIG. 3 is a diagram showing an example of an address translation table 221 of the embodiment of the present technology.

FIG. 4 is a diagram showing an example of an unused physical address list 222 of the embodiment of the present technology.

FIG. 5 is a diagram showing an example of a relationship between position information and data in the first embodiment of the present technology.

FIG. 6 is a diagram showing a configuration example of a memory 300 of the embodiment of the present technology.

FIG. 7 is a diagram showing a configuration example of one tile of a memory cell array 310 of the embodiment of the present technology.

FIG. 8 is a diagram showing a configuration example of a memory cell 311 of the embodiment of the present technology.

FIG. 9 is a diagram showing a three-dimensional image example of the memory cell array 310 of the embodiment of the present technology.

FIG. 10 is a diagram showing a resistance state of the memory cell 311 of the embodiment of the present technology.

FIG. 11 is a diagram showing an example of a buffer held in an access buffer 370 of the embodiment of the present technology.

FIG. 12 is a diagram showing an example of data held in the access buffer 370 in set processing of the first embodiment of the present technology.

FIG. 13 is a diagram showing an example of data held in the access buffer 370 in reset processing of the first embodiment of the present technology.

FIG. 14 is a flow chart showing an example of a processing procedure of read command processing of the memory controller 200 of the first embodiment of the present technology.

FIG. 15 is a flow chart showing an example of a processing procedure of drift refresh processing of the memory controller 200 of the first embodiment of the present technology.

FIG. 16 is a flow chart showing an example of a processing procedure of write command processing of the memory controller 200 of the first embodiment of the present technology.

FIG. 17 is a flow chart showing an example of a processing procedure of drift refresh request processing of the memory 300 of the first embodiment of the present technology.

FIG. 18 is a flow chart showing an example of a processing procedure of program request processing of the memory 300 of the first embodiment of the present technology.

FIG. 19 is a flow chart showing an example of a processing procedure of set processing of the memory 300 of the first embodiment of the present technology.

FIG. 20 is a flow chart showing an example of a processing procedure of reset processing of the memory 300 of the first embodiment of the present technology.

FIG. 21 is a flow chart showing an example of a processing procedure of read request processing of the memory 300 of the first embodiment of the present technology.

FIG. 22 is a flow chart showing an example of a processing procedure of drift refresh processing of a memory controller 200 of a second embodiment of the present technology.

FIG. 23 is a diagram showing an example of a buffer held in an access buffer 370 after verification processing in a third embodiment of the present technology.

FIG. 24 is a flow chart showing an example of a processing procedure of drift refresh request processing of a memory 300 of the third embodiment of the present technology.

FIG. 25 is a diagram showing an example of drift refresh target data of a fourth embodiment of the present technology.

FIG. 26 is a flow chart showing an example of a processing procedure of drift refresh processing of a memory controller 200 of the fourth embodiment of the present technology.

FIG. 27 is a diagram showing an example of data held in an access buffer 370 in set processing of a fifth embodiment of the present technology.

FIG. 28 is a flow chart showing an example of a processing procedure of drift refresh processing of a memory controller 200 of the fifth embodiment of the present technology.

FIG. 29 is a flow chart showing an example of a processing procedure of drift refresh request processing of the memory 300 of the fifth embodiment of the present technology.

### MODES FOR CARRYING OUT THE INVENTION

Hereinafter, modes for carrying out the present technology (hereinafter referred to as embodiments) will be described. The description will be given in the following order.

1. First embodiment (Example of writing error-corrected data to unused physical address)

2. Second embodiment (Example of writing error-corrected data to original area where drift refresh has been executed)

3. Third embodiment (Example of using pulse having same voltage as reset pulse as drift refresh pulse)

4. Fourth embodiment (Example of executing drift refresh even in memory cell in low resistance state where no drift occurs)

5. Fifth embodiment (Example of collectively executing drift refresh processing and processing of bringing back low resistance state in memory)

### 1. First Embodiment

### [Configuration of Information Processing System]

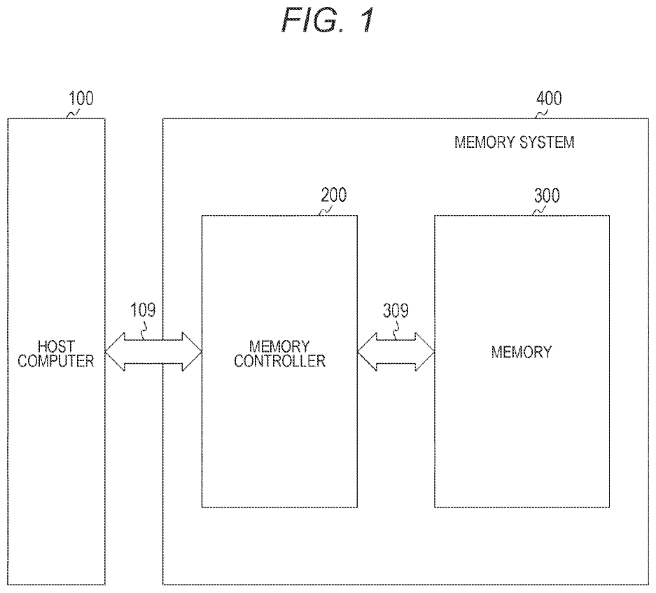

FIG. 1 is a diagram showing a configuration example of an information processing system of an embodiment of the present technology. The information processing system includes a host computer 100, a memory controller 200, and a memory 300. A memory system 400 includes the memory controller 200 and the memory 300.

The host computer 100 issues commands to the memory 300 to give an instruction on data read processing, data write processing, and the like. The host computer 100 includes a processor that executes processing as the host computer 100, and a controller interface for exchanging information with the memory controller 200. A signal line 109 connects the host computer 100 and the memory controller 200.

The memory controller 200 controls a request for the memory 300 according to a command from the host computer 100. A signal line 309 connects the memory controller 200 and the memory 300.

The memory 300 includes a control unit and a memory cell array. The control unit of the memory 300 accesses a memory cell according to a request from the memory controller 200. The memory cell in the memory 300 is assumed to be a non-volatile memory (NVM).

When a write command is received from the host computer 100, the memory controller 200 receives data from the host computer 100, issues a write request to the memory 300, and sends and writes the data received from the host computer 100 to the memory 300.

When a read command is received from the host computer 100, the memory controller 200 issues a read request to the memory 300, reads data from the memory 300, and transfers the data read from the memory 300 to the host computer 100.

When the host computer 100 executes a write command or a read command, a logical address is used as an address representing position information of data in the memory system 400. An area represented by one logical address is 512 bytes in size. The logical address that can be specified by the host computer 100 is 0x000000 to 0xDFFFFF (“0x” indicates that the number following it is a hexadecimal number, the same applies hereafter), which corresponds to seven gigabytes in size.

When the memory controller 200 makes a write request (request) or a read request to the memory 300, a physical address is used as an address representing position information of data. An area represented by one physical address is 525 bytes (4200 bits) in size. Of the 525 bytes, 512 consecutive bytes from the beginning are the data received from the host system by the write command, and the remaining 13 bytes are an error correction code (ECC). The physical address that can be specified by the memory controller 200 is 0x000000 to 0xFFFFFF, which corresponds to eight gigabytes in size.

### [Configuration of Memory Controller]

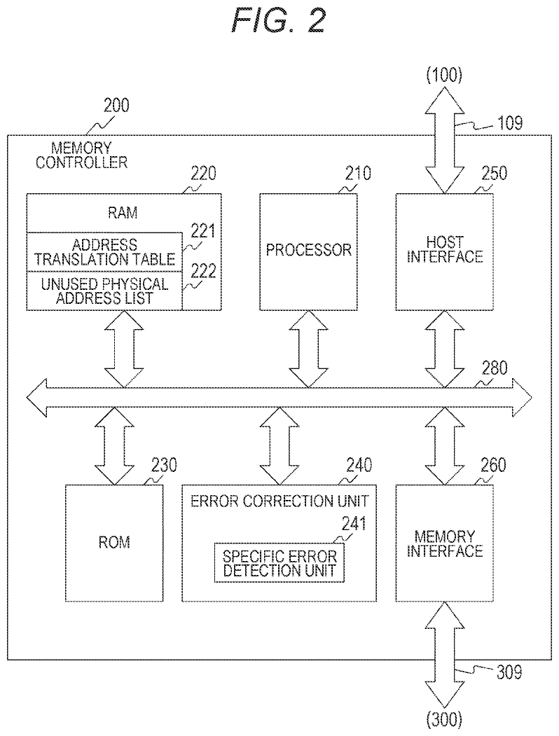

FIG. 2 is a diagram showing a configuration example of the memory controller 200 of the embodiment of the present technology.

The memory controller 200 includes a processor 210, a RAM 220, a ROM 230, an error correction unit 240, a host interface 250, and a memory interface 260. These components are connected to each other by a bus 280.

The processor 210 is a processor that executes processing of the memory controller 200. The processor 210 uses the RAM 220 as a working memory to execute software stored in the ROM 230. Note that the processor 210 is an example of a control unit described in “CLAIMS”.

The RAM 220 is a volatile memory and operates as a working memory for operating software for controlling the memory system 400. Additionally, the RAM 220 is used to hold data for managing the memory 300, temporarily hold data transferred between the host computer 100 and the memory controller 200, and temporarily hold data transferred between the memory controller 200 and the memory 300, for example.

The RAM 220 holds an address translation table 221 and an unused physical address list 222 as data for managing the memory 300. The address translation table 221 is information for associating a logical address specified by the host computer 100 with a physical address of the memory 300. The unused physical address list 222 is information for holding physical addresses that are not assigned to logical addresses.

The ROM 230 is a non-volatile memory and stores software and the like for controlling the memory system 400.

The error correction unit 240 calculates an error correction code of data recorded in the memory 300 and executes error correction processing of data read from the memory 300. The size of an error correction code is assumed to be 13 bytes as described above, and the correction capability of the error correction unit 240 in this case is eight bits.

The error correction unit 240 includes a specific error detection unit 241. The specific error detection unit 241 has a function of detecting, from errors detected from data read from the memory 300, a bit whose data before correction is “0” and data after correction is “1” as a specific error, identifying the position of the bit, and holding the position as position information. Here, position information is a bit string of 4200 bits (525 bytes), and is data in which a bit corresponding to a bit whose data before correction is “0” and data after correction is “1” is represented by “1”, and other bits are represented by “0”, for example. Note that the specific error detection unit 241 is an example of a detection unit described in “CLAIMS”.

The host interface 250 is an interface with the host computer 100. The host interface 250 communicates with the host computer 100, receives commands from the host computer 100, and sends and receives data to and from the host computer 100. The signal line 109 connects the memory controller 200 and the host computer 100.

The memory interface 260 is an interface with the memory 300. The memory interface 260 communicates with the memory 300, sends requests processed by the memory 300, and sends and receives data to and from the memory 300. The signal line 309 connects the memory controller 200 and the memory 300.

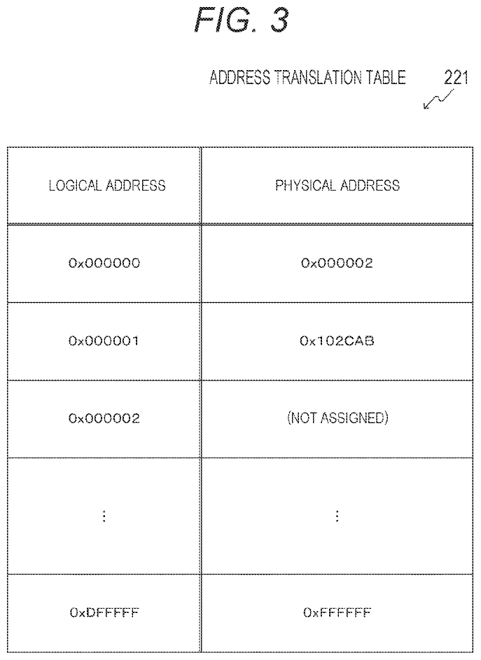

FIG. 3 is a diagram showing an example of the address translation table 221 of the embodiment of the present technology.

The address translation table 221 is a table that holds a physical address of the memory 300 in association with a logical address specified by the host computer 100. Among the logical addresses, for a logical address having no corresponding physical address assigned thereto, an invalid value is held as the address. On the other hand, among the physical addresses, a physical address having no corresponding logical address assigned thereto is managed in the unused physical address list 222.

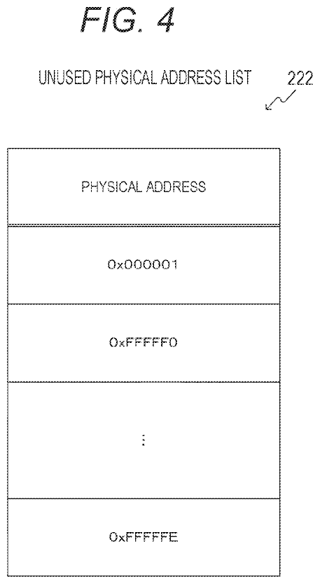

FIG. 4 is a diagram showing an example of the unused physical address list 222 of the embodiment of the present technology.

The unused physical address list 222 is a list that holds unused physical addresses that are not assigned to logical addresses. A physical address held in the unused physical address list 222 is used as a new logical address area as needed. At that time, the physical address held in the unused physical address list 222 is deleted from the list and is registered in the address translation table 221 as a physical address corresponding to a new logical address.

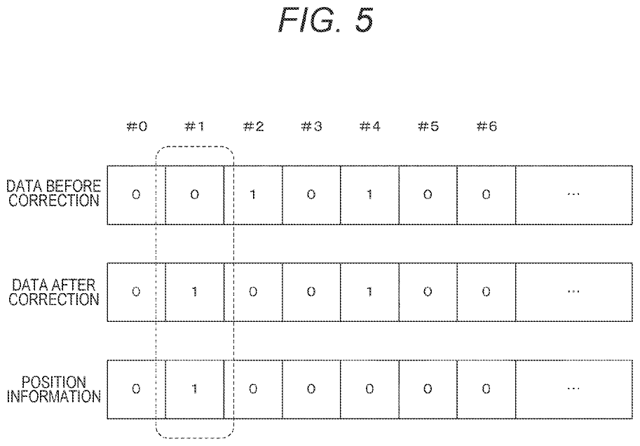

FIG. 5 is a diagram showing an example of a relationship between position information and data in the first embodiment of the present technology.

Data corrected by the error correction unit 240 is compared with data before correction by the specific error detection unit 241. Then, as shown by the dotted line, a bit of position information corresponding to a bit whose data before correction is “0” and data after correction is “1” is set to “1”. On the other hand, other bits of the position information are set to “0”.

### [Configuration of Memory]

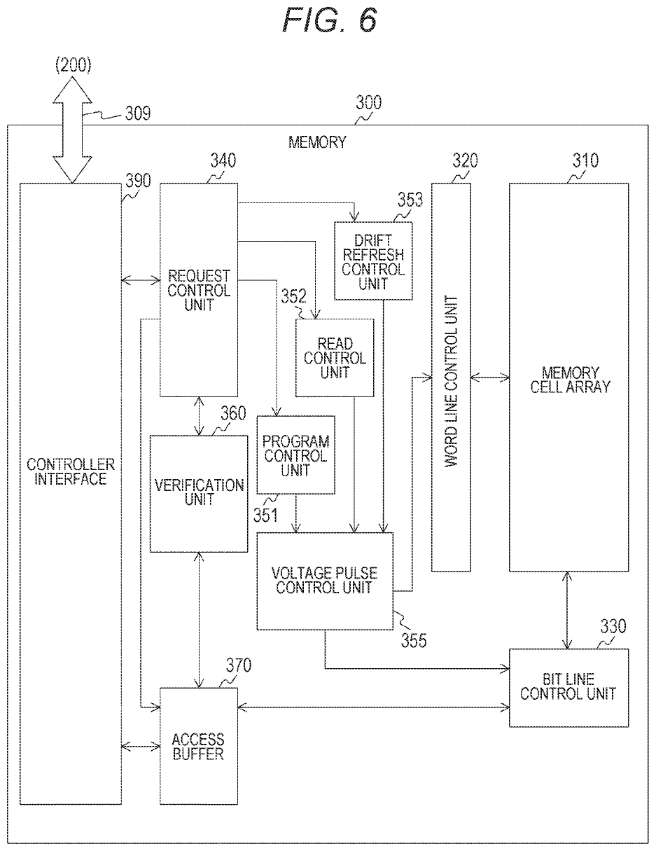

FIG. 6 is a diagram showing a configuration example of the memory 300 of the embodiment of the present technology.

The memory 300 includes a memory cell array 310, a word line control unit 320, a bit line control unit 330, a request control unit 340, a program control unit 351, a read control unit 352, a drift refresh control unit 353, a voltage pulse control unit 355, a verification unit 360, an access buffer 370, and a controller interface 390.

The memory cell array 310 is formed by arranging multiple memory cells in an array (two-dimensional or matrix). In this embodiment, the memory cell is assumed to be a non-volatile ReRAM.

The word line control unit 320 controls word lines of the memory cell array 310. The bit line control unit 330 controls bit lines of the memory cell array 310.

The request control unit 340 performs control for processing a request from the memory controller 200. Note that the request control unit 340 is an example of the control unit described in “CLAIMS”.

The program control unit 351 performs control when a program (write) is performed on the memory cell array 310. The program control unit 351 performs control to apply a set pulse or a reset pulse to the memory cell array 310 through the voltage pulse control unit 355, according to a set or reset execution instruction from the request control unit 340.

The read control unit 352 performs control when reading from the memory cell array 310. The read control unit 352 performs control to apply a read pulse to the memory cell array 310 through the voltage pulse control unit 355, according to a read execution instruction from the request control unit 340.

The drift refresh control unit 353 performs control when performing a drift refresh on the memory cell array 310 to eliminate drift. The drift refresh control unit 353 performs control to apply a drift refresh pulse to the memory cell array 310 through the voltage pulse control unit 355, according to a drift refresh execution instruction from the request control unit 340.

The voltage pulse control unit 355 performs control to apply a voltage pulse to the memory cell array 310 under the control of the program control unit 351, the read control unit 352, and the drift refresh control unit 353.

The verification unit 360 performs verification when a program (write) is performed on the memory cell array 310. Note that the verification unit 360 is an example of the detection unit described in “CLAIMS”.

The access buffer 370 holds a buffer used when performing a program on or reading the memory cell array 310. A specific example of the buffer held in the access buffer 370 will be described later.

The controller interface 390 is an interface with the memory controller 200. The signal line 309 connects the memory controller 200 and the memory 300.

Note that the memory cell array 310 is an example of a memory cell array described in “CLAIMS”, and the portion of the memory 300 other than the memory cell array 310 and the memory controller 200 are an example of a storage control device described in “CLAIMS”.

### [Memory Cell Array]

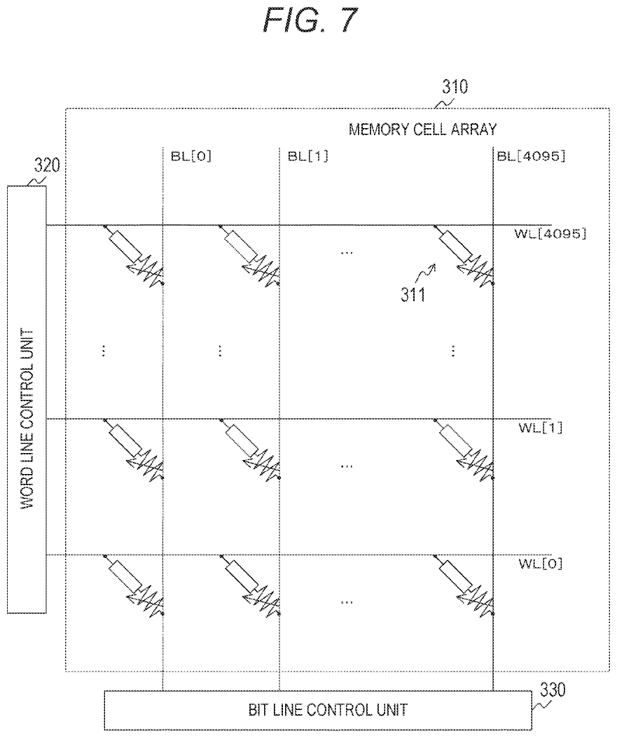

FIG. 7 is a diagram showing a configuration example of one tile of the memory cell array 310 of the embodiment of the present technology.

In this embodiment, the memory cell array 310 includes 4200 tiles. One tile of the memory cell array 310 has a configuration in which memory cells 311 are connected between 4096 word lines 329 from WL [0] to WL [4095] and 4096 bit lines 339 from BL [0] to BL [4095], for example. The word line 329 is controlled by the word line control unit 320, and the bit line 339 is controlled by the bit line control unit 330.

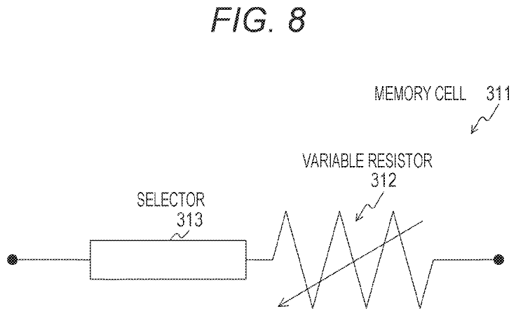

FIG. 8 is a diagram showing a configuration example of the memory cell 311 of the embodiment of the present technology.

In this embodiment, the memory cell 311 is a ReRAM. The memory cell 311 has a variable resistor 312 and a selector 313 connected in series. One end of the variable resistor 312 is connected to the bit line 339 and one end of the selector 313 is connected to the word line 329.

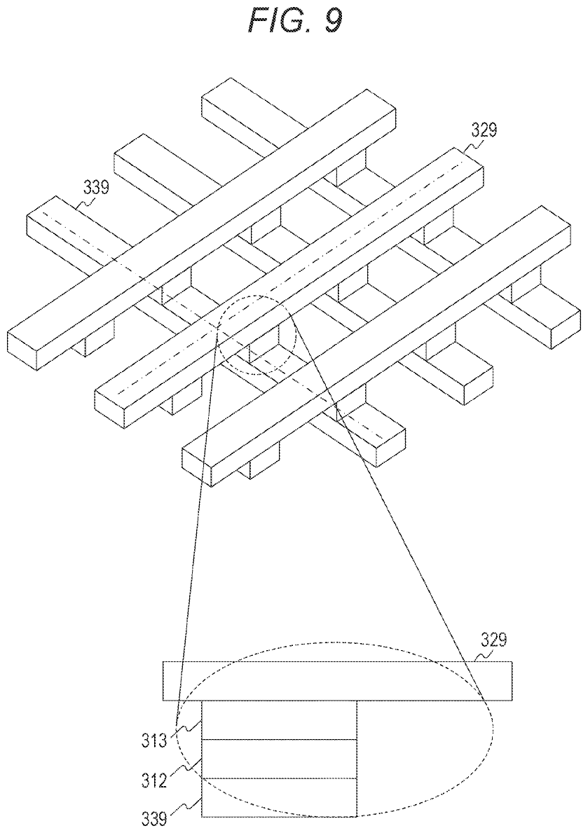

FIG. 9 is a diagram showing a three-dimensional image example of the memory cell array 310 of the embodiment of the present technology.

As shown in FIG. 9, the memory cell 311 including the selector 313 and the variable resistor 312 is sandwiched between the upper-layer word line 329 and the lower-layer bit line 339. As a result, it is possible to arrange the memory cell 311 at a position where the word line 329 and the bit line 339 intersect, and control the memory cell 311.

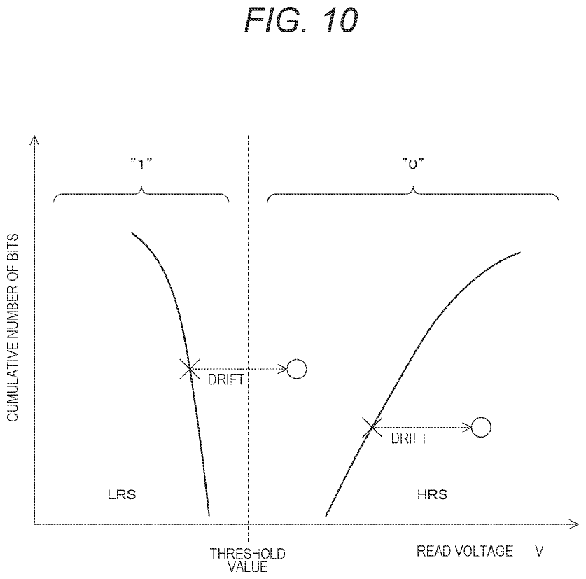

FIG. 10 is a diagram showing a resistance state of the memory cell 311 of the embodiment of the present technology.

As described above, the memory cell 311 is assumed to be a ReRAM, and shows either a low resistance state (LRS) or a high resistance state (HRS). As shown in FIG. 10, the distribution of the cumulative number of bits when a read voltage V is applied to the memory cell 311 is classified into either a low resistance state or a high resistance state with a threshold value as a boundary.

If the selector 313 is not snapped (i.e., not turned on) for a long time, drift may occur. Due to the effect of this drift, the voltage required for the selector 313 to snap increases. In a state where the variable resistor 312 of the memory cell 311 is in a low resistance state and drift is occurring, the selector 313 does not snap even when a read voltage is applied, and no current flows through the memory cell 311. As a result, the resistance state of the variable resistor 312 that is actually a low resistance state is erroneously determined to be a high resistance state. On the other hand, for the memory cell 311 which was originally in a high resistance state, there is no change in the high resistance state even when drift is occurring, and no data error occurs.

For this reason, in this embodiment, the memory cell 311 which is actually in a low resistance state but is erroneously determined to be in a high resistance state is detected as a specific error, and a drift refresh is executed to eliminate the drift caused by the error. This drift refresh is executed by applying a drift refresh voltage higher than the read voltage to the memory cell 311.

Here, the voltage applied to the memory cell 311 will be described. Note that in the following description, a reading voltage is Vread, a setting voltage is Vset, a reset voltage is Vreset, and a drift refreshing voltage is Vdr.

When reading data from the memory cell 311, by applying voltage pulses “−Vread/2” and “+Vread/2” to the word line 329 and bit line 339 connected to the selected memory cell 311, respectively, the read pulse Vread is applied to the selected memory cell 311. As a result, it is determined whether the resistance state of the variable resistor 312 is a low resistance state (LRS) or a high resistance state (HRS) on the basis of the flowing current.

When applying a set pulse to the memory cell 311, by applying voltage pulses “−Vset/2” and “+Vset/2” to the word line 329 and bit line 339 connected to the selected memory cell 311, respectively, the set pulse Vset is applied to the selected memory cell 311. As a result, if the resistance state of the variable resistor 312 is a high resistance state (HRS), the resistance state transitions to a low resistance state (LRS).

When applying a reset pulse to the memory cell 311, by applying voltage pulses “+Vreset/2” and “−Vreset/2” to the word line 329 and bit line 339 connected to the selected memory cell 311, respectively, the set pulse Vreset is applied to the selected memory cell 311. If the resistance state of the variable resistor 312 is a low resistance state (LRS), the resistance state transitions to a high resistance state (HRS). The direction in which the voltage is applied is the opposite direction of the set pulse.

When applying a drift refresh pulse to memory cell 311, by applying voltage pulses “+Vdr/2” and “−Vdr/2” to the word line 329 and bit line 339 connected to the selected memory cell 311, respectively, the drift refresh pulse Vdr is applied to the selected memory cell 311. The direction in which the voltage is applied is the same direction as the reset pulse.

When the voltage required for the selector to snap is Vsnap, Vsnap rises due to the effect of drift. When the voltage applied to the selector 313 at the time of application of the read pulse is less than Vsnap, the current required to detect a low resistance state (LRS) does not flow even if the resistance state of the variable resistor 312 is a low resistance state (LRS). Hence, the state of the variable resistor 312 is determined to be a high resistance state (HRS).

If a reset pulse or drift refresh pulse is applied while the variable resistor 312 is in a high resistance state (HRS), the variable resistor 312 enters a state that does not transition to a low resistance state (LRS) with a set pulse, and cannot record data normally.

Similarly, if a set pulse is applied while the variable resistor 312 is in a low resistance state (LRS), the variable resistor 312 enters a state that does not transition to a high resistance state (HRS) with a reset pulse, and cannot record data normally.

In this embodiment, “Vread<Vset” and “Vread<Vdr<Vreset” are assumed in order to reduce the load on the memory cell 311. Note, however, that as in the embodiment described later, in order to reduce the circuit for generating the drift refresh pulse, “Vdr=Vreset” may be set to use a pulse having the same voltage as the reset pulse as the drift refresh pulse.

The read pulse, set pulse, refresh pulse, and drift refresh pulse are applied to one selected memory cell 311 for each tile. Note, however, that the pulses may be simultaneously applied to the memory cells 311 of all 4200 tiles or some of the tiles.

### [Buffer]

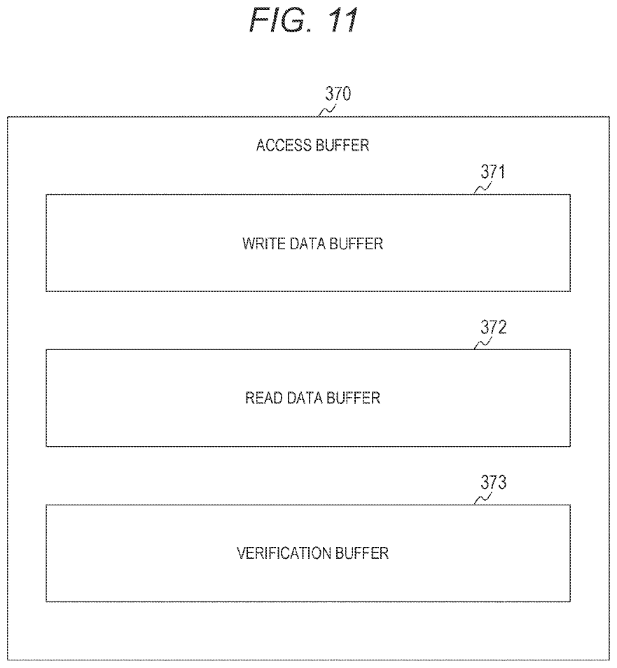

FIG. 11 is a diagram showing an example of a buffer held in the access buffer 370 of the embodiment of the present technology.

The access buffer 370 holds a write data buffer 371, a read data buffer 372, and a verification buffer 373.

The write data buffer 371 is a buffer that holds write data to the memory cell array 310. The read data buffer 372 is a buffer that holds read data read from the memory cell array 310. The verification buffer 373 is a buffer that holds a result of comparison by the verification unit 360. The size of each of the write data buffer 371, the read data buffer 372, and the verification buffer 373 is assumed to be 4224 bits (528 bytes).

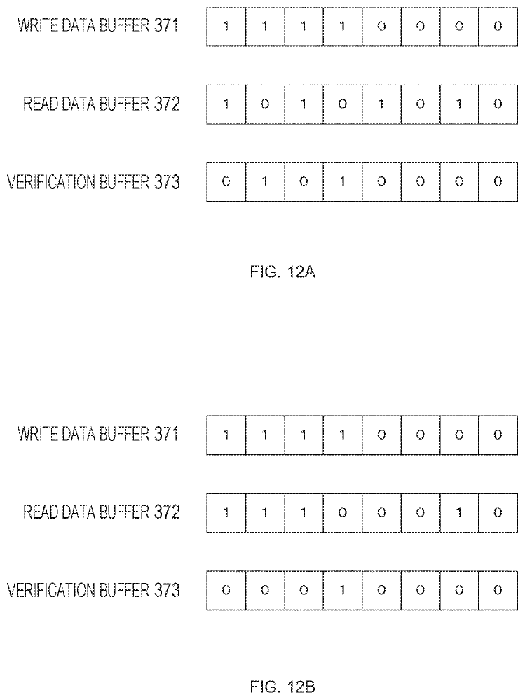

FIG. 12 is a diagram showing an example of data held in the access buffer 370 in set processing of the first embodiment of the present technology. Set processing is processing of causing the memory cell 311 in a high resistance state (HRS) to transition to a low resistance state (LRS).

The write data buffer 371 holds write data transferred from the memory controller 200. At the time of set processing, the request control unit 340 reads data from an area indicated by a write address and holds it in the read data buffer 372.

The verification unit 360 compares data held in the read data buffer 372 with data held in the write data buffer 371 in bit units, and identifies a memory cell to apply the set pulse. In set processing, the set pulse is applied to a bit whose data value held in the write data buffer 371 is “1” and whose data value held in the read data buffer 372 is “0”. That is, as shown in a of FIG. 12, the verification buffer 373 holds data in which “1” is set for a bit value corresponding to a memory cell that requires application of the set pulse and “0” is set for a bit value corresponding to a memory cell that does not require application of the set pulse.

After applying the set pulse, the request control unit 340 reads data from the written area and holds it in the read data buffer 372 for verification. The verification unit 360 compares the data held in the read data buffer 372 with the data held in the write data buffer 371 in bit units, and verifies whether or not the set processing has been performed normally. The bit to be compared is a bit whose data value held in the write data buffer 371 is “1”.

A bit whose data value held in the write data buffer 371 is “1” and whose value held in the read data buffer 372 is “0” is “fail”. A bit whose data value held in the write data buffer 371 is “1” and whose value held in the read data buffer 372 is “1” is “pass”. As shown in b of FIG. 12, the verification buffer 373 holds “1” for the “fail” bit, “0” for the “pass” bit, and “0” for the bit that is not a comparison target.

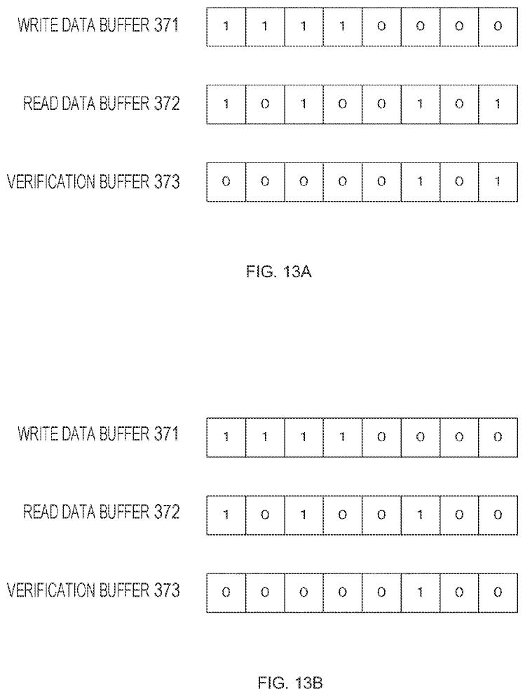

FIG. 13 is a diagram showing an example of data held in the access buffer 370 in reset processing of the first embodiment of the present technology. Reset processing is processing of causing the memory cell 311 in a low resistance state (LRS) to transition to a high resistance state (HRS).

The write data buffer 371 holds write data transferred from the memory controller 200. At the time of reset processing, the request control unit 340 reads data from an area indicated by a write address and holds it in the read data buffer 372.

The verification unit 360 compares data held in the read data buffer 372 with data held in the write data buffer 371 in bit units, and identifies a memory cell to apply the reset pulse. In reset processing, a bit whose data value held in the write data buffer 371 is “0” and data value held in the read data buffer 372 is “1” is the target of reset pulse application. That is, as shown in a of FIG. 13, the verification buffer 373 holds data in which “1” is set for a bit value corresponding to a memory cell that requires application of the reset pulse and “0” is set for a bit value corresponding to a memory cell that does not require application of the reset pulse.

After applying the reset pulse, the request control unit 340 reads data from the written area and holds it in the read data buffer 372 for verification. The verification unit 360 compares the data held in the read data buffer 372 with the data held in the write data buffer 371 in bit units, and verifies whether or not the reset processing has been performed normally. The bit to be compared is a bit whose data value held in the write data buffer 371 is “0”.

A bit whose data value held in the write data buffer 371 is “0” and whose value held in the read data buffer 372 is “1” is “fail”. A bit whose data value held in the write data buffer 371 is “0” and whose value held in the read data buffer 372 is “0” is “pass”. As shown in b of FIG. 13, the verification buffer 373 holds “1” for the “fail” bit, “0” for the “pass” bit, and “0” for the bit that is not a comparison target.

### [Operation]

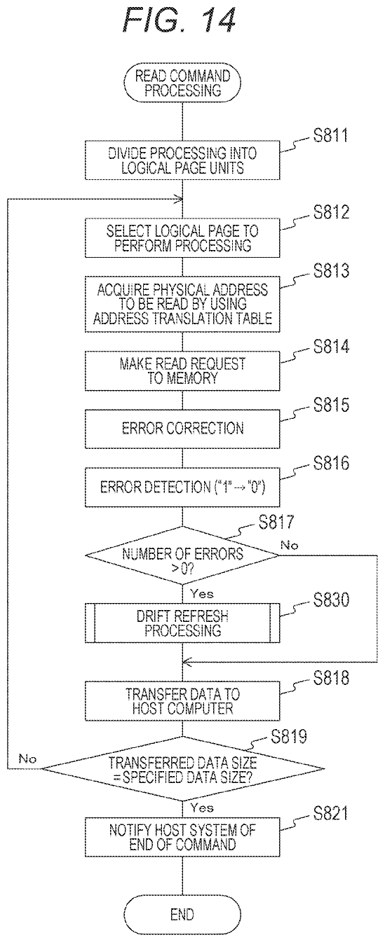

FIG. 14 is a flow chart showing an example of a processing procedure of read command processing of the memory controller 200 of the first embodiment of the present technology. When a read command is issued from the host computer 100, the memory controller 200 executes read command processing according to the following procedure.

The processor 210 divides the processing into logical address units on the basis of the starting logical address and data size of the read target received through the host interface 250 (step S811). One logical address is executed in one processing. For example, if “0” is specified as the starting address of the read target and “1” is specified as the data size thereof, the processing is performed once. Additionally, if “0” is specified as the starting logical address of the read target and “2” is specified as the data size thereof, the processing is divided into two processings.

The processor 210 determines the logical address to be read (step S812). The target logical address is determined in order from the starting logical address of the read target. For example, if “0” is specified as the starting logical address of the read target and “2” is specified as the data size thereof, “0” is determined as the logical address to execute the processing first. Then, “1” is determined as the next target logical address.

The processor 210 translates the logical address determined as the read target into a physical address by referring to the address translation table 221 held in the RAM 220 (step S813).

The processor 210 specifies the physical address translated in step S813 and makes a read request to the memory 300 (step S814). The data read from the memory 300 by this read request is 4200 bits (525 bytes) including the error correction code (ECC).

The 4200-bit (525-byte) data read from the memory 300 is subjected to error correction processing by the error correction unit 240 (step S815). The specific error detection unit 241 of the error correction unit 240 detects, in bit units, data read as “0” among the pieces of data written as “1” from the 4200-bit (525-byte) data as a specific error, and holds its position information (step S816).

If there is a specific error detected by the specific error detection unit 241 (step S817: Yes), drift refresh processing is performed (step S830). The contents of drift refresh processing will be described later.

Note that while the presence or absence of a specific error is determined to branch the processing in this embodiment, in order to reduce overhead by reducing the execution frequency of the drift refresh processing (step S830), a threshold value may be set for the determination. For example, the processing may be branched by determining whether the number of data read as “0” among the pieces of data written as “1” is equal to or greater than a threshold value.

The processor 210 transfers data from the error correction unit 240 to the host computer 100 through the host interface 250 (step S818). The data to be transferred is 512-byte data obtained by excluding the 13-byte error correction code (ECC) from the 525-byte data subjected to error correction.

The processor 210 determines whether the total data size transferred to the host computer 100 by the read command processing matches the data size specified by the read command (step S819). If the data sizes do not match (step S819: No), the processing from step S812 is repeated. If the data sizes match (step S819: Yes), the processor 210 notifies the host computer 100 of the end of the read command processing (step S821).

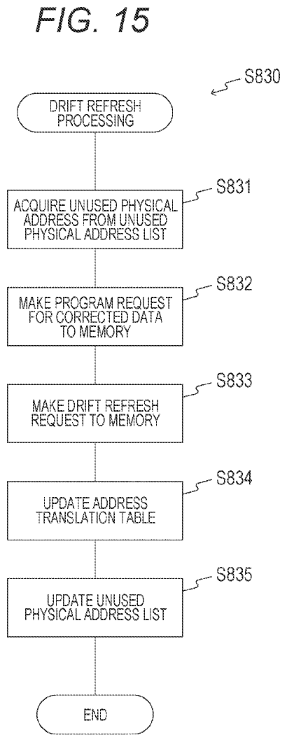

FIG. 15 is a flow chart showing an example of a processing procedure of drift refresh processing (step S830) of the memory controller 200 of the first embodiment of the present technology.

The processor 210 acquires an unused physical address from the unused physical address list 222 (step S831).

The processor 210 specifies the physical address acquired in step S831 and makes a program request for 4200-bit (525-byte) data subjected to error correction (step S815) to the memory 300 (step S832). This physical address becomes a new area for storing corrected data.

The processor 210 specifies a physical address determined by the specific error detection unit 241 that a specific error has occurred, and makes a drift refresh request to the memory 300 (step S833). At that time, position information indicating the bit position of the specific error detected by the specific error detection unit 241 (step S816) is also transferred to the memory 300.

The processor 210 updates the physical address corresponding to the original logical address (step S812) in the address translation table 221 with the physical address acquired in step S831 (step S834). As a result, the new area for storing corrected data is associated with the original logical address.

The processor 210 deletes the newly acquired physical address (step S831) from the unused physical address list 222 (step S835). Additionally, the processor 210 adds the physical address for which the drift refresh request was made (step S833) to the unused physical address list 222 (step S835).

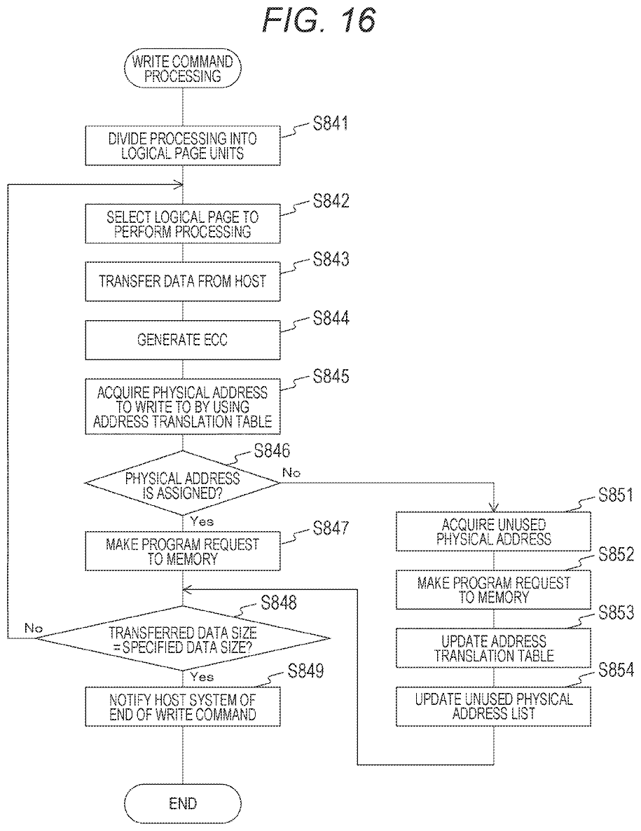

FIG. 16 is a flow chart showing an example of a processing procedure of write command processing of the memory controller 200 of the first embodiment of the present technology. When a write command is issued from the host computer 100, the memory controller 200 executes write command processing according to the following procedure.

The processor 210 divides the processing into logical address units on the basis of the starting logical address and data size of the write target received via the host interface 250 (step S841). One logical address is executed in one processing. For example, if “0” is specified as the starting address of the write target and “1” is specified as the data size thereof, the processing is performed once. Additionally, if “0” is specified as the starting logical address of the write target and “2” is specified as the data size thereof, the processing is divided into two processings.

The processor 210 determines the logical address to write to (step S842). The target logical address is determined in order from the starting logical address of the write target. For example, if “0” is specified as the starting logical address of the write target and “2” is specified as the data size thereof, “0” is determined as the logical address to execute the processing first. Then, “1” is determined as the next target logical address.

The processor 210 receives 512-byte write data from the host computer 100 through the host interface 250 (step S843). The error correction unit 240 generates a 13-byte error correction code from the 512-byte write data, and generates 525-byte data including the 512-byte write data (step S844).

The processor 210 translates the logical address determined as the write target into a physical address by using the address translation table 221 held in the RAM 220 (step S845). At that time, the processor 210 determines the presence or absence of a physical address assigned to the logical address. If a physical address has already been assigned (step S846: Yes), writing is performed to the memory 300. That is, the processor 210 specifies the physical address acquired in step S845 and makes a program request for the 525-byte data generated in step S844 to the memory 300 (step S847).

On the other hand, if no physical address has been assigned (step S846: No), the processor 210 acquires a physical address by referring to the unused physical address list 222 (step S851). Then, by specifying the acquired physical address, a program request for the 525-byte data generated in step S844 is made to the memory 300 (step S852). Thereafter, the processor 210 updates the physical address corresponding to the logical address of the write target (step S845) in the address translation table 221 with the physical address acquired in step S851 (step S853). Additionally, the processor 210 deletes the newly acquired physical address (step S851) from the unused physical address list 222 (step S854).

The processor 210 determines whether the total data size transferred to the memory 300 by the write command processing matches the data size specified by the write command (step S848). If the data sizes do not match (step S848: No), the processing from step S842 is repeated. If the data sizes match (step S848: Yes), the processor 210 notifies the host computer 100 of the end of the write command processing (step S849).

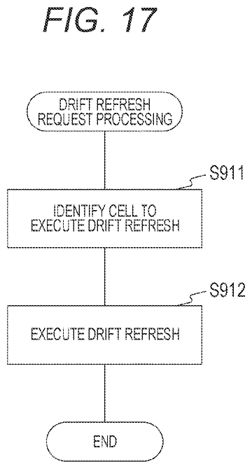

FIG. 17 is a flow chart showing an example of a processing procedure of drift refresh request processing of the memory 300 of the first embodiment of the present technology. Upon receipt of a drift refresh request (step S833) from the memory controller 200, the memory 300 executes drift refresh request processing according to the following procedure.

Upon receipt of the drift refresh request and a physical address from the memory controller 200 through the controller interface 390, the request control unit 340 starts the drift refresh request processing. The physical address is transferred to and held in the request control unit 340 from the controller interface 390. Position information required for the drift refresh request processing is transferred to and held in the write data buffer 371 from the controller interface 390. Note that as described above, in the position information, a memory cell to be subjected to a drift refresh is represented by “1” and a memory cell not to be subjected to a drift refresh is represented by “0”.

The request control unit 340 identifies the memory cell 311 to apply the drift refresh pulse from the value (position information) held in the write data buffer 371 (step S911). Then, the request control unit 340 specifies the identified memory cell 311 to execute a drift refresh, and instructs the drift refresh control unit 353 to execute the drift refresh (step S912).

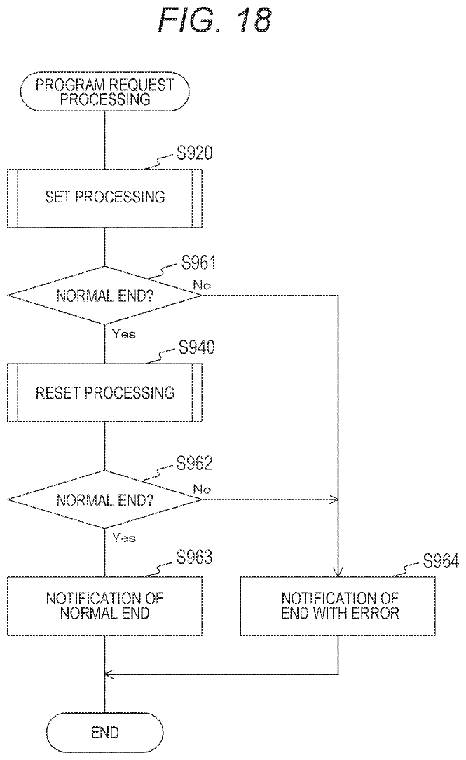

FIG. 18 is a flow chart showing an example of a processing procedure of program request processing of the memory 300 of the first embodiment of the present technology. Upon receipt of a program request (steps S832, S847, S852) from the memory controller 200, the memory 300 executes program request processing according to the following procedure.

Upon receipt of the program request and a physical address from the memory controller 200 through the controller interface 390, the request control unit 340 starts the program request processing. Write data required for the program request processing is transferred to and held in the write data buffer 371 through the controller interface 390. The physical address is transferred to and held in the request control unit 340 from the controller interface 390.

The request control unit 340 executes set processing (step S920). The set processing is processing of causing the resistance state of the variable resistor 312 to transition from a high resistance state (HRS) to a low resistance state (LRS), and the processing procedure will be described later.

The request control unit 340 determines whether the set processing (step S920) ends normally, and if it ends with an error (step S961: No), the request control unit 340 notifies the memory controller 200 of the end with error through the controller interface 390 (step S964).

If the set processing ends normally (step S961: Yes), the request control unit 340 executes reset processing (step S940). The reset processing is processing of causing the resistance state of the variable resistor 312 to transition from a low resistance state (LRS) to a high resistance state (HRS), and the processing procedure will be described later.

The request control unit 340 determines whether the reset processing (step S940) ends normally, and if it ends with an error (step S962: No), the request control unit 340 notifies the memory controller 200 of the end with error through the controller interface 390 (step S964). If the set processing ends normally (step S962: Yes), the request control unit 340 notifies the memory controller 200 of the normal end through the controller interface 390 (step S963).

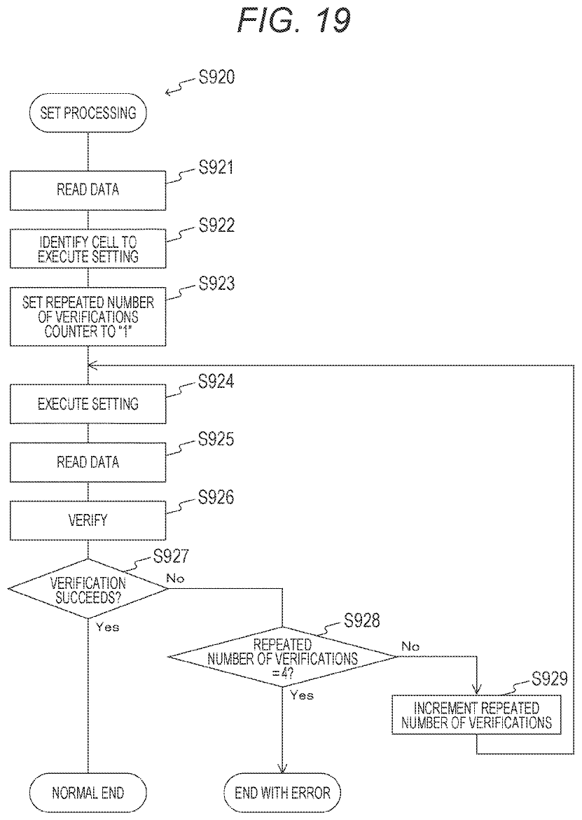

FIG. 19 is a flow chart showing an example of a processing procedure of set processing (step S920) of the memory 300 of the first embodiment of the present technology. Note that the data size handled in the set processing is assumed to be 4200 bits (525 bytes).

In the set processing, a memory cell specified by the memory controller 200 is changed to a low resistance state (LRS). Information on the memory cell to be changed to a low resistance state is transferred to and held in the write data buffer 371 from the memory controller 200 through the controller interface 390 as 4200-bit (525-byte) bit string data before the start of the set processing.

The request control unit 340 specifies a physical address specified by the memory controller 200, instructs the read control unit 352 to execute a 4200-bit (525-byte) read, and reads the data (step S921). The read data is transferred to and held in the read data buffer 372.

The request control unit 340 instructs the verification unit 360 to compare the data held in the read data buffer 372 (step S921) with data held in the write data buffer 371. The verification unit 360 compares the data held in the read data buffer 372 with the data held in the write data buffer 371 in bit units, and identifies a memory cell to apply the set pulse (step S922). As described above, the set pulse is applied to a bit whose data value held in the write data buffer 371 is “1” and whose data value held in the read data buffer 372 is “0”.

The request control unit 340 sets, in advance, the value of a verification counter for counting the repeated number of verifications to “1” (step S923).

The request control unit 340 specifies the value of the verification buffer 373 to the program control unit 351, gives an instruction on application of the set pulse, and executes the setting (step S924). Thereafter, the request control unit 340 performs reading in order to verify whether or not the setting has been performed normally (step S925). That is, the request control unit 340 specifies a physical address specified by the memory controller 200, instructs the read control unit 352 to execute a 4200-bit (525-byte) read, and reads the data. The read data is transferred to and held in the read data buffer 372.

Then, the request control unit 340 instructs the verification unit 360 to compare the data held in the read data buffer 372 (step S925) with the data held in the write data buffer 371. The verification unit 360 performs verification by comparing the data held in the read data buffer 372 with the data held in the write data buffer 371 (step S926). Note that as described above, a bit whose data value held in the write data buffer 371 is “1” and whose value held in the read data buffer 372 is “0” is “fail”. A bit whose data value held in the write data buffer 371 is “1” and whose value held in the read data buffer 372 is “1” is “pass”.

The verification buffer 373 holds “1” for the “fail” bit, “0” for the “pass” bit, and “0” for the bit that is not a comparison target. If all the bits held in the verification buffer 373 are “0”, the verification unit 360 notifies the request control unit 340 that the comparison result is “pass”. If not, the verification unit 360 notifies the request control unit 340 that the comparison result is “fail”.

If the verification unit 360 notifies the request control unit 340 of “pass” of the setting (step S927: Yes), the request control unit 340 ends the set processing normally. On the other hand, if the verification unit 360 notifies the request control unit 340 of “fail” of the setting (step S927: No), and the value of the verification counter has not reached “4” (step S928: No), the verification counter is incremented (step S929). Then, the processing from step S924 is repeated. If the value of the verification counter has reached “4” (step S928: Yes), the processing ends with an error without executing setting any further.

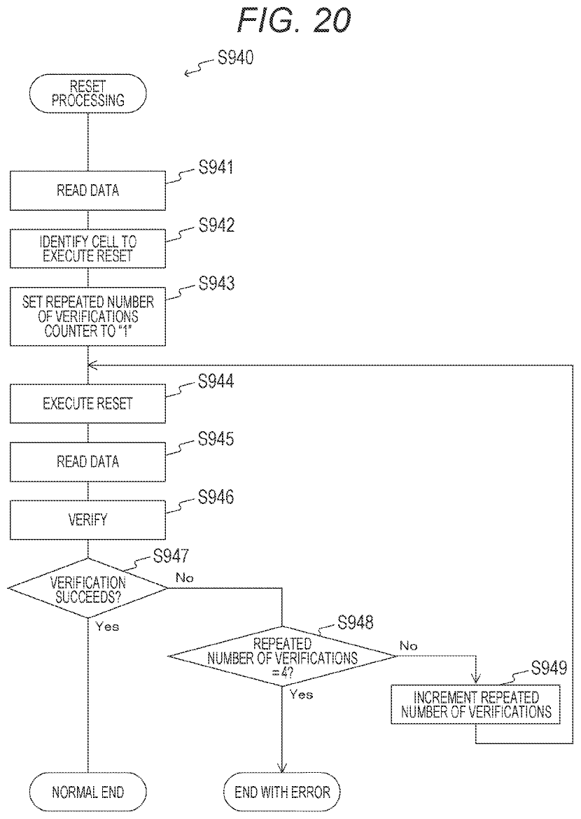

FIG. 20 is a flow chart showing an example of a processing procedure of reset processing (step S940) of the memory 300 of the first embodiment of the present technology. Note that the data size handled in the reset processing is assumed to be 4200 bits (525 bytes).

In the reset processing, a memory cell specified by the memory controller 200 is changed to a high resistance state (HRS). Information on the memory cell to be changed to a high resistance state is transferred to and held in the write data buffer 371 from the memory controller 200 through the controller interface 390 as 4200-bit (525-byte) bit string data before the start of the set processing.

The request control unit 340 specifies the physical address specified by the memory controller 200, instructs the read control unit 352 to execute a 4200-bit (525-byte) read, and reads the data (step S941). The read data is transferred to and held in the read data buffer 372.

The request control unit 340 instructs the verification unit 360 to compare the data held in the read data buffer 372 (step S941) with data held in the write data buffer 371. The verification unit 360 compares the data held in the read data buffer 372 with the data held in the write data buffer 371 in bit units, and identifies a memory cell to apply the reset pulse (step S942). As described above, the reset pulse is applied to a bit whose data value held in the write data buffer 371 is “0” and whose data value held in the read data buffer 372 is “1”.

The request control unit 340 sets, in advance, the value of the verification counter for counting the repeated number of verifications to “1” (step S943).

The request control unit 340 specifies the value of the verification buffer 373 to the program control unit 351, gives an instruction on application of a set pulse, and executes the reset (step S944). Thereafter, the request control unit 340 performs reading in order to verify whether or not the reset has been performed normally (step S945). That is, the request control unit 340 specifies a physical address specified by the memory controller 200, instructs the read control unit 352 to execute a 4200-bit (525-byte) read, and reads the data. The read data is transferred to and held in the read data buffer 372.

Then, the request control unit 340 instructs the verification unit 360 to compare the data held in the read data buffer 372 (step S945) with the data held in the write data buffer 371. The verification unit 360 performs verification by comparing the data held in the read data buffer 372 with the data held in the write data buffer 371 (step S946). Note that as described above, a bit whose data value held in the write data buffer 371 is “0” and whose value held in the read data buffer 372 is “1” is “fail”. A bit whose data value held in the write data buffer 371 is “0” and whose value held in the read data buffer 372 is “0” is “pass”.

The verification buffer 373 holds “1” for the “fail” bit, “0” for the “pass” bit, and “0” for the bit that is not a comparison target. If all the bits held in the verification buffer 373 are “0”, the verification unit 360 notifies the request control unit 340 that the comparison result is “pass”. If not, the verification unit 360 notifies the request control unit 340 that the comparison result is “fail”.

If the verification unit 360 notifies the request control unit 340 of “pass” of the reset (step S947: Yes), the request control unit 340 ends the reset processing normally. On the other hand, if the verification unit 360 notifies the request control unit 340 of “fail” of the reset (step S947: No), and the value of the verification counter has not reached “4” (step S948: No), the verification counter is incremented (step S949). Then, the processing from step S944 is repeated. If the value of the verification counter has reached “4” (step S948: Yes), the processing ends with an error without executing any more resets.

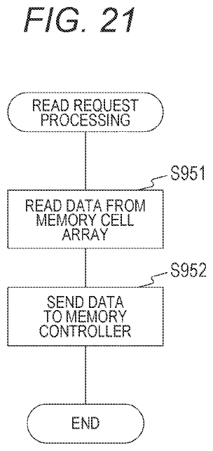

FIG. 21 is a flow chart showing an example of a processing procedure of read request processing of the memory 300 of the first embodiment of the present technology. Upon receipt of a read request (step S814) from the memory controller 200, the memory 300 executes read request processing according to the following procedure.

Upon receipt of the read request and a physical address from the memory controller 200 through the controller interface 390, the request control unit 340 starts the read request processing. The physical address is transferred to and held in the request control unit 340 through the controller interface 390. In the read request processing, 4200-bit (525-byte) data is transferred from the memory 300 to the memory controller 200.

The request control unit 340 specifies the physical address specified by the controller interface 390, instructs the read control unit 352 to execute a data read of 4200 bits (525 bytes), and reads the data (step S951). The read data is transferred to and held in the read data buffer 372.

The request control unit 340 transfers the 4200-bit (525-byte) data held in the read data buffer 372 to the memory controller 200 through the controller interface 390 (step S952).

As described above, in the first embodiment of the present technology, the memory cell 311 which is actually in a low resistance state but is erroneously determined to be in a high resistance state is detected as a specific error, and a drift refresh is executed. As a result, the generated drift can be eliminated and use of the memory cell 311 can be continued. Consequently, it is possible to prevent deterioration of the memory cell 311 caused by further applying the set pulse to the memory cell 311 in the low resistance state (LRS), and maintain a highly reliable state of the memory cell 311 for a long period of time to extend memory life.

### 2. Second Embodiment

In the first embodiment described above, the error-corrected data is written to a new area (unused physical address). However, in this second embodiment, it is assumed that the original area (physical address) where a drift refresh is executed is used as it is. Note that since the configuration of the information processing system is similar to that of the first embodiment described above, detailed description thereof will be omitted.

### [Operation]

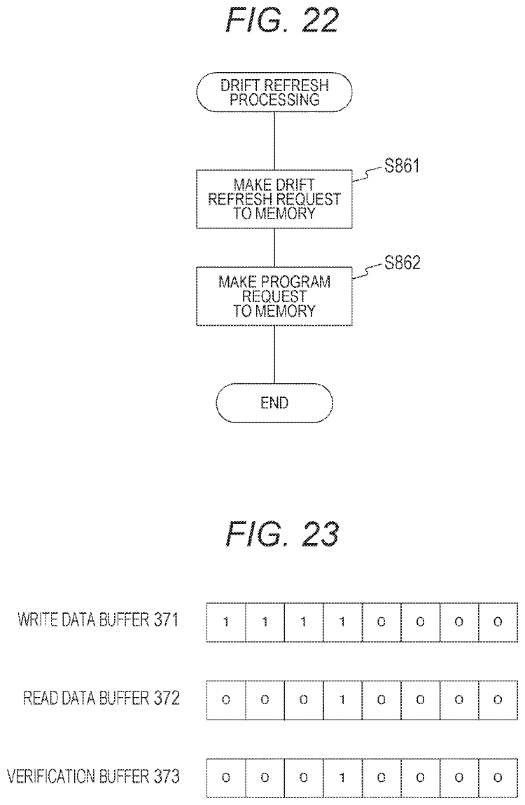

FIG. 22 is a flow chart showing an example of a processing procedure of drift refresh processing of a memory controller 200 of the second embodiment of the present technology. The drift refresh processing of the memory controller 200 of the second embodiment corresponds to the processing in step S830 of the first embodiment described above.

A processor 210 specifies a physical address determined by a specific error detection unit 241 that a specific error has occurred, and makes a drift refresh request to a memory 300 (step S861). At that time, position information indicating a bit position of the specific error detected by the specific error detection unit 241 (step S816 in above first embodiment) is also transferred to the memory 300.

The processor 210 specifies the physical address where the drift refresh is executed and makes a program request for 525-byte data subjected to error correction (step S815 in above first embodiment) to the memory 300 (step S862). As a result, a set pulse is applied to a memory cell 311 that has transitioned to a high resistance state (HRS) by the drift refresh, so that the memory cell 311 is brought back to a low resistance state (LRS).

In this second embodiment, since no new area is secured, it is not necessary to update an address translation table 221 or an unused physical address list 222 as in the first embodiment described above.

As described above, according to the second embodiment of the present technology, after a drift refresh is executed, corrected data is written to the area. Hence, the memory cell 311 can be used without updating the address translation table 221 or the unused physical address list 222.

### 3. Third Embodiment

In the first embodiment described above, “Vread<Vset” and “Vread<Vdr<Vreset” are assumed in order to reduce the load on the memory cell 311. In this third embodiment, “Vdr=Vreset”. That is, a pulse having the same voltage as the reset pulse is used as the drift refresh pulse. With this configuration, the drift refresh control unit 353 can be shared with the program control unit 351, and the circuit for generating the drift refresh pulse can be reduced. Note that since other parts of the configuration of the information processing system are similar to those of the first embodiment described above, detailed description thereof will be omitted.

### [Buffer]

FIG. 23 is a diagram showing an example of a buffer held in an access buffer 370 after verification processing in the third embodiment of the present technology.

In the third embodiment, drift refresh processing is performed on a memory cell 311 in a low resistance state (LRS). A drift refresh pulse Vdr at this time has the same voltage as a reset pulse Vreset. Accordingly, the memory cell 311 subjected to drift refresh processing transitions to a high resistance state (HRS) if it is in a normal state.

In the example of FIG. 23, in a write data buffer 371, “1” is set for the bit to be subjected to drift refresh processing. After verification processing, reading is performed from the area mentioned above, and the read data is held in a read data buffer 372. A bit whose data value held in the write data buffer 371 is “1” and whose data value held in the read data buffer 372 is “1” is “fail”.

A bit whose data value held in the write data buffer 371 is “1” and whose data value held in the read data buffer 372 is “0” is “pass”. The verification buffer 373 holds “1” for the “fail” bit, “0” for the “pass” bit, and “0” for the bit that is not a comparison target.

### [Operation]

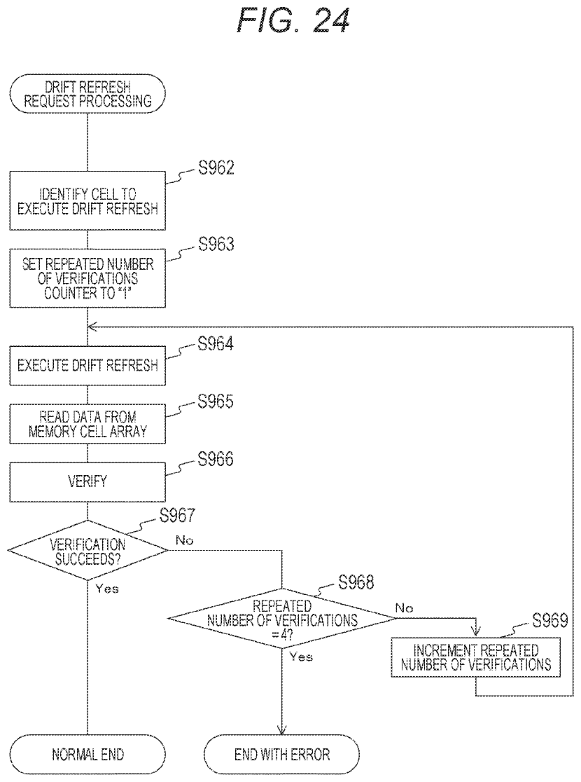

FIG. 24 is a flow chart showing an example of a processing procedure of drift refresh request processing of a memory 300 of the third embodiment of the present technology. Upon receipt of a drift refresh request (step S833 in above first embodiment) from a memory controller 200, the memory 300 executes drift refresh request processing according to the following procedure.

The memory controller 200 transfers a physical address to perform a drift refresh and position information at the time of the drift refresh request. In the position information, a memory cell to be subjected to a drift refresh is represented by “1” and a memory cell not to be subjected to a drift refresh is represented by “0”.

A request control unit 340 identifies the memory cell 311 to apply the drift refresh pulse from the value (position information) held in the write data buffer 371 (step S962).

The request control unit 340 sets, in advance, the value of a verification counter for counting the repeated number of verifications to “1” (step S963).

The request control unit 340 specifies the memory cell 311 to execute a drift refresh identified in step S962, and instructs a drift refresh control unit 353 to execute the drift refresh (step S964).

Thereafter, the request control unit 340 performs reading in order to verify whether or not the drift refresh has been performed normally (step S965). That is, the request control unit 340 instructs a verification unit 360 to compare the data held in the read data buffer 372 in step S965 with the data held in the write data buffer 371. As a result, the verification unit 360 compares the data held in the read data buffer 372 with the data held in the write data buffer 371 (step S966). The bit to be compared is a bit whose data value held in the write data buffer 371 is “1”.

As a result of the comparison, if all the bits held in the verification buffer 373 are “0”, the verification unit 360 determines that the comparison result is “pass” and notifies the request control unit 340 of the normal end. If not, the verification unit 360 notifies the request control unit 340 that the comparison result is “fail”.

If the verification unit 360 notifies the request control unit 340 of “pass” of the drift refresh (step S967: Yes), the request control unit 340 ends the drift refresh processing normally. On the other hand, if the verification unit 360 notifies the request control unit 340 of “fail” of the drift refresh (step S967: No), and the value of the verification counter has not reached “4” (step S968: No), the verification counter is incremented (step S969). Then, the processing from step S964 is repeated. In a case of resetting by repeating the drift refresh, the memory cell 311 to apply the pulse is the memory cell 311 in which “1” is held in the value of the corresponding bit of the verification buffer 373. If the value of the verification counter has reached “4” (step S968: Yes), the processing ends with an error without executing any more drift refreshes.

As described above, in the third embodiment of the present technology, a pulse having the same voltage as the reset pulse is used as the lift refresh pulse. With this configuration, the drift refresh control unit 353 can be shared with the program control unit 351, and the circuit for generating the drift refresh pulse can be reduced.

### 4. Fourth Embodiment

In the third embodiment described above, the drift refresh is executed for the memory cell 311 in which drift occurs. However, in this fourth embodiment, a drift refresh is also executed for a memory cell 311 in a low resistance state (LRS) in which no drift occurs. As a result, the entire 4200-bit (525-byte) data is caused to transition to a high resistance state (HRS) so that drift does not occur even if it is left for a long time. Note that since the configuration of the information processing system is similar to that of the first embodiment described above, detailed description thereof will be omitted.

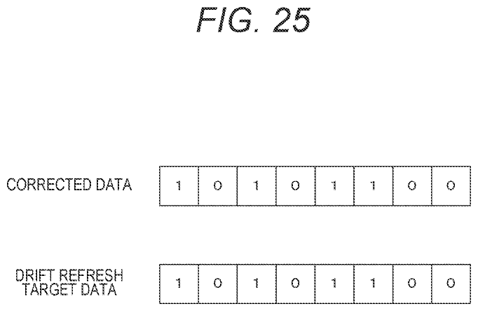

FIG. 25 is a diagram showing an example of drift refresh target data of the fourth embodiment of the present technology.

The drift refresh target data is acquired from data error-corrected by an error correction unit 240 before execution of drift refresh processing. That is, the memory cell 311 whose error-corrected data indicates “1” (LRS) is a drift refresh target, while the memory cell 311 whose error-corrected data indicates “0” (HRS) is not a lift refresh target.

### [Operation]

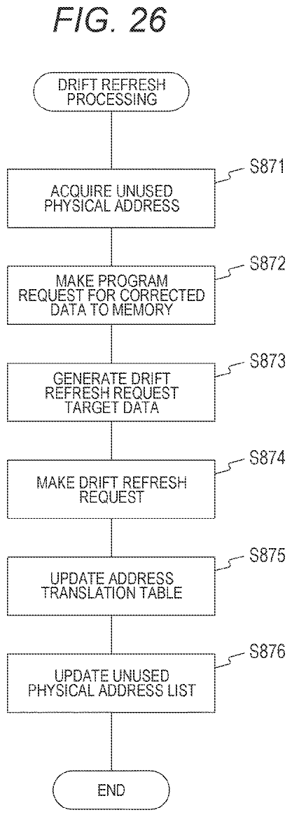

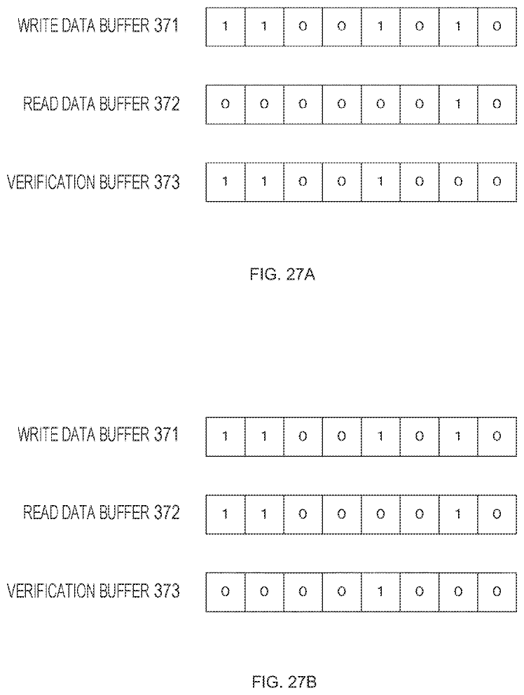

FIG. 26 is a flow chart showing an example of a processing procedure of the drift refresh processing of a memory controller 200 of the fourth embodiment of the present technology. The drift refresh processing of the memory controller 200 of the fourth embodiment corresponds to the processing in step S830 in the first embodiment described above.

A processor 210 acquires an unused physical address from an unused physical address list 222 (step S871).

The processor 210 specifies the physical address acquired in step S831 and makes a program request for data subjected to error correction (step S815 in above first embodiment) to the memory 300 (step S872). This physical address becomes a new area for storing corrected data.

The processor 210 generates drift refresh request target data in a RAM 220 from the data subjected to error correction (step S815 in above first embodiment) (step S873). As described above, in the memory cell 311 as a target of the drift refresh, the resistance state of the memory cell 311 is a low resistance state (LRS), and the corrected data value is a bit indicating

The processor 210 transfers the drift refresh target data generated in the RAM 220 as position information, specifies the physical address acquired in step S871, and makes a drift refresh request (step S874).

The processor 210 updates the physical address corresponding to the original logical address (step S812 in above first embodiment) in an address translation table 221 with the physical address acquired in step S871 (step S875). As a result, the new area for storing corrected data is associated with the original logical address.

The processor 210 deletes the newly acquired physical address (step S871) from an unused physical address list 222 (step S876). Additionally, the processor 210 adds the physical address for which the drift refresh request was made (step S874) to the unused physical address list 222 (step S876).

As described above, in the fourth embodiment, the drift refresh is also executed for the memory cell 311 in a low resistance state (LRS) in which no drift occurs. As a result, it is possible to cause the entire 4200-bit (525-byte) data to transition to a high resistance state (HRS) so that drift does not occur even if it is left for a long time.

### 5. Fifth Embodiment

In the second embodiment described above, the memory controller 200 performs control to separately request the drift refresh processing and the processing of bringing back the resistance state that transitions to a high resistance state (HRS) by the drift refresh processing to a low resistance state (LRS). In the fifth embodiment, these processings are combined into one request and executed as a function of a memory 300.

### [Buffer]

FIG. 27 is a diagram showing an example of data held in an access buffer 370 in set processing of the fifth embodiment of the present technology.

The write data buffer 371 holds write data transferred from the memory controller 200. At the time of set processing, the request control unit 340 reads data from an area indicated by a write address and holds it in the read data buffer 372.

The verification unit 360 compares data held in the read data buffer 372 with data held in the write data buffer 371 in bit units, and identifies a memory cell to apply the set pulse. In set processing, the set pulse is applied to a bit whose data value held in the write data buffer 371 is “1” and whose data value held in the read data buffer 372 is “0”. That is, as shown in a of FIG. 27, the verification buffer 373 holds data in which “1” is set for a bit value corresponding to a memory cell that requires application of the set pulse and “0” is set for a bit value corresponding to a memory cell that does not require application of the set pulse.

After applying the set pulse, the request control unit 340 reads data from the written area and holds it in the read data buffer 372 for verification. The verification unit 360 compares the data held in the read data buffer 372 with the data held in the write data buffer 371 in bit units, and verifies whether or not the set processing has been performed normally. The bit to be compared is a bit whose data value held in the write data buffer 371 is “1”.

A bit whose data value held in the write data buffer 371 is “1” and whose value held in the read data buffer 372 is “0” is “fail”. A bit whose data value held in the write data buffer 371 is “1” and whose value held in the read data buffer 372 is “1” is “pass”. As shown in b of FIG. 27, the verification buffer 373 holds “1” for the “fail” bit, “0” for the “pass” bit, and “0” for the bit that is not a comparison target.

### [Operation]

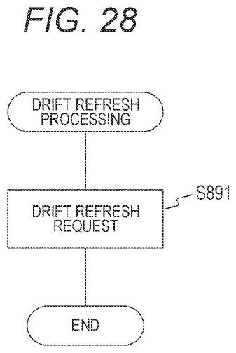

FIG. 28 is a flow chart showing an example of a processing procedure of drift refresh processing of the memory controller 200 of the fifth embodiment of the present technology.

A processor 210 specifies a physical address determined by a specific error detection unit 241 that a specific error has occurred, and makes a drift refresh request to the memory 300 (step S891). At that time, position information indicating a bit position of the specific error detected by the specific error detection unit 241 (step S816 in above first embodiment) is also transferred to the memory 300.

The drift refresh request in the fifth embodiment includes processing of bringing back the resistance state that transitions to a high resistance state (HRS) by the drift refresh processing to a low resistance state (LRS).

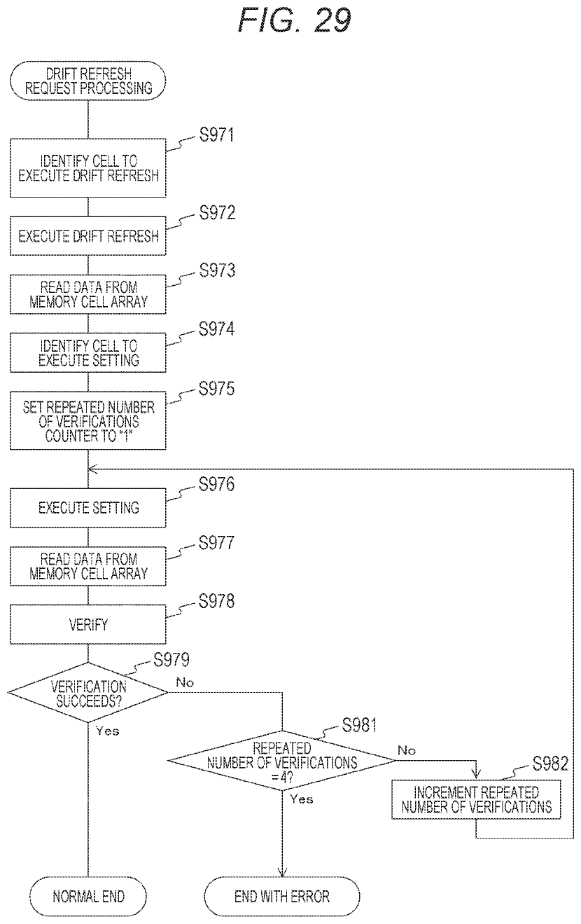

FIG. 29 is a flow chart showing an example of a processing procedure of drift refresh request processing of the memory 300 of the fifth embodiment of the present technology. Upon receipt of a drift refresh request (step S891) from the memory controller 200, the memory 300 executes drift refresh request processing according to the following procedure.

The memory controller 200 transfers a physical address to perform a drift refresh and position information at the time of the drift refresh request. In the position information, a memory cell to be subjected to a drift refresh is represented by “1” and a memory cell not to be subjected to a drift refresh is represented by “0”.

The request control unit 340 identifies a memory cell 311 to apply the drift refresh pulse from the value (position information) held in the write data buffer 371 (step S971).

The request control unit 340 specifies the memory cell 311 to execute a drift refresh identified in step S971, and instructs a drift refresh control unit 353 to execute the drift refresh (step S972).

The request control unit 340 specifies the physical address where the drift refresh is executed, instructs a read control unit 352 to execute a 4200-bit (525-byte) read, and reads the data (step S973). The read data is transferred to and held in the read data buffer 372.

The request control unit 340 instructs the verification unit 360 to compare the data held in the read data buffer 372 in step S973 with the position information held in the write data buffer 371. The verification unit 360 compares the data held in the read data buffer 372 with the data held in the write data buffer 371 in bit units, and identifies a memory cell to apply the set pulse (step S974). As described above, the set pulse is applied to a bit whose data value held in the write data buffer 371 is “1” and whose data value held in the read data buffer 372 is “0”.

The request control unit 340 sets, in advance, the value of a verification counter for counting the repeated number of verifications to “1” (step S975).

The request control unit 340 specifies the value of the verification buffer 373 to a program control unit 351, gives an instruction on application of the set pulse, and executes the setting (step S976). Thereafter, the request control unit 340 performs reading in order to verify whether or not the setting has been performed normally (step S977). That is, the request control unit 340 specifies a physical address specified by the memory controller 200, instructs the read control unit 352 to execute a 4200-bit (525-byte) read, and reads the data. The read data is transferred to and held in the read data buffer 372.

Then, the request control unit 340 instructs the verification unit 360 to compare the data held in the read data buffer 372 (step S977) with the data held in the write data buffer 371. The verification unit 360 performs verification by comparing the data held in the read data buffer 372 with the data held in the write data buffer 371 (step S978).

The verification buffer 373 holds “1” for the “fail” bit, “0” for the “pass” bit, and “0” for the bit that is not a comparison target. If all the bits held in the verification buffer 373 are “0”, the verification unit 360 notifies the request control unit 340 that the comparison result is “pass”. If not, the verification unit 360 notifies the request control unit 340 that the comparison result is “fail”.

If the verification unit 360 notifies the request control unit 340 of “pass” of the setting (step S979: Yes), the request control unit 340 ends the set processing normally. On the other hand, if the verification unit 360 notifies the request control unit 340 of “fail” of the setting (step S979: No), and the value of a verification counter has not reached “4” (step S981: No), the verification counter is incremented (step S982). Then, the processing from step S976 is repeated. In a case of executing setting again, the memory cell 311 to apply the pulse is the memory cell 311 in which “1” is held in the value of the corresponding bit of the verification buffer 373. If the value of the verification counter has reached “4” (step S981: Yes), the processing ends with an error without executing setting any further.

As described above, according to the fifth embodiment, the drift refresh processing and the processing of bringing back the low resistance state (LRS) can be collectively executed in the memory 300 by one request from the memory controller 200.

Note that the above-described embodiments are an example for embodying the present technology, and the matters in the embodiments and the matters specifying the invention in the claims have a corresponding relationship. Similarly, the matters specifying the invention in the claims and the matters having the same names in the embodiments of the present technology have a correspondence relationship. Note, however, that the present technology is not limited to the embodiments, and can be embodied by variously modifying the embodiments without departing from the gist of the present technology.

Additionally, the processing procedure described in the above embodiments may be regarded as a method including a series of these procedures, or may be regarded as a program for causing a computer to execute the series of procedures or a recording medium storing the program. As the recording medium, for example, a compact disc (CD), a minidisc (MD), a digital versatile disc (DVD), a memory card, a Blu-ray (registered trademark) disc, or the like can be used.

Note that the effect described in the present specification is merely an illustration and is not restrictive, and other effects can be obtained.

Note that the present technology can also be configured in the following manner.

(1) A storage control device including:

a detection unit that detects, in a memory cell array in which each bit is in any one of first and second states, a transition bit that should be in the first state but is in the second state; and

a control unit that performs control to supply, to the transition bit, a drift refresh voltage higher than a read voltage required for reading from the memory cell array.

(2) The storage control device according to (1) above, in which

the detection unit detects the transition bit by comparing values before and after error correction.

(3) The storage control device according to (2) above, in which

the control unit performs control to secure a new area not including the transition bit in the memory cell array and store the error-corrected value.

(4) The storage control device according to (2) above, in which

the control unit performs control to store the error-corrected value in an area where the drift refresh voltage has been supplied to the transition bit.

(5) The storage control device according to any one of (1) to (4) above, in which

the control unit performs control to supply, to the transition bit, a reset voltage higher than the read voltage and aimed for transition from the first state to the second state as the drift refresh voltage.

(6) The storage control device according to any one of (1) to (5) above, in which

the control unit performs control to supply the drift refresh voltage also to a bit in the first state other than the transition bit.

(7) The storage control device according to (1) above, in which

the control unit performs control to supply, to a predetermined area of the memory cell array, a reset voltage higher than the read voltage and aimed for transition from the first state to the second state as the drift refresh voltage,

the detection unit detects, as the transition bit, a bit that transitions to the second state by receiving supply of the reset voltage, and

the control unit performs control to supply, to the transition bit, a set voltage higher than the read voltage and aimed for transition from the second state to the first state.

(8) A storage device including:

a memory cell array in which each bit is in any one of first and second states;

a detection unit that detects a transition bit that should be in the first state but is in the second state in the memory cell array; and

a control unit that performs control to supply, to the transition bit, a drift refresh voltage higher than a read voltage required for reading from the memory cell array.

(9) The storage device according to (8) above, in which

the memory cell array is a resistive random access memory (ReRAM),

the first state is a low resistance state, and

the second state is a high resistance state.

(10) The storage device according to (8) or (9) above, in which

the memory cell array is a non-volatile memory.

(11) A storage control method including:

a procedure of detecting, in a memory cell array in which each bit is in any one of first and second states, a transition bit that should be in the first state but is in the second state; and a procedure of performing control to supply, to the transition bit, a drift refresh voltage higher than a read voltage required for reading from the memory cell array.

### REFERENCE SIGNS LIST

100 Host computer
200 Memory controller
210 Processor
221 Address translation table
222 Unused physical address list
240 Error correction unit
241 Specific error detection unit
250 Host interface
260 Memory interface
280 Bus
300 Memory
310 Memory cell array
311 Memory cell
312 Variable resistor
313 selector
320 Word line control unit
330 Bit line control unit
340 Request control unit
351 Program control unit
352 Read control unit
353 Drift refresh control unit
355 Voltage pulse control unit
360 Verification unit
370 Access buffer
371 Write data buffer
372 Read data buffer
373 Verification buffer
390 Controller interface
400 Memory system

1. A storage control device comprising:
a detection unit that detects, in a memory cell array in which each bit is in any one of first and second states, a transition bit that should be in the first state but is in the second state; and
a control unit that performs control to supply, to the transition bit, a drift refresh voltage higher than a read voltage required for reading from the memory cell array.

2. The storage control device according to claim 1, wherein
the detection unit detects the transition bit by comparing values before and after error correction.

3. The storage control device according to claim 2, wherein
the control unit performs control to secure a new area not including the transition bit in the memory cell array and store the error-corrected value.

4. The storage control device according to claim 2, wherein
the control unit performs control to store the error-corrected value in an area where the drift refresh voltage has been supplied to the transition bit.

5. The storage control device according to claim 1, wherein
the control unit performs control to supply, to the transition bit, a reset voltage higher than the read voltage and aimed for transition from the first state to the second state as the drift refresh voltage.

6. The storage control device according to claim 1, wherein
the control unit performs control to supply the drift refresh voltage also to a bit in the first state other than the transition bit.

7. The storage control device according to claim 1, wherein
the control unit performs control to supply, to a predetermined area of the memory cell array, a reset voltage higher than the read voltage and aimed for transition from the first state to the second state as the drift refresh voltage,
the detection unit detects, as the transition bit, a bit that transitions to the second state by receiving supply of the reset voltage, and
the control unit performs control to supply, to the transition bit, a set voltage higher than the read voltage and aimed for transition from the second state to the first state.

8. A storage device comprising:
a memory cell array in which each bit is in any one of first and second states;
a detection unit that detects a transition bit that should be in the first state but is in the second state in the memory cell array; and
a control unit that performs control to supply, to the transition bit, a drift refresh voltage higher than a read voltage required for reading from the memory cell array.

9. The storage device according to claim 8, wherein
the memory cell array is a resistive random access memory (ReRAM),
the first state is a low resistance state, and
the second state is a high resistance state.

10. The storage device according to claim 8, wherein
the memory cell array is a non-volatile memory.

11. A storage control method comprising:
a procedure of detecting, in a memory cell array in which each bit is in any one of first and second states, a transition bit that should be in the first state but is in the second state; and
a procedure of performing control to supply, to the transition bit, a drift refresh voltage higher than a read voltage required for reading from the memory cell array.
